(19) United States
(12) Patent Application Publication
(10) Pub. No.: US 2011/0220485 A1
(43) Pub. Date: Sep. 15, 2011

(54) METHOD FOR MANUFACTURING DEVICE AND MANUFACTURING APPARATUS

(75) Inventors: Akira Ishiguro, Fukuoka-ken (JP); Masakazu Sawano, Fukuoka-ken (JP); Ryota Yoshioka, Fukuoka-Ken (JP); Kazuhiko Komatsu, Fukuoka-ken (JP)

(73) Assignee: Kabushiki Kaisha Toshiba, Tokyo (JP)

(21) Appl. No.: 12/878,974

(22) Filed: Sep. 9, 2010

(30) Foreign Application Priority Data
Mar. 10, 2010 (JP) 2010-053616

(51) Int. Cl. C23C 14/34

(52) U.S. Cl. 204/192.1; 204/298.02

(57) ABSTRACT

In one embodiment, a method is disclosed for manufacturing a device including forming a film on an object of processing using sputtering. The method can form a first film of a first sputtered particle on the object of processing at a first position. The first sputtered particle travels in a direction intersecting a major surface of a sputtering target. The object of processing and the sputtering target do not overlap as viewed in plan at the first position. In addition, the method can form a second film of a second sputtered particle on the first film at a second position. The second sputtered particle travels in a direction substantially orthogonal to the major surface of the sputtering target. The object of processing and the sputtering target at least partially overlap as viewed in plan at the second position. The second sputtered particle is screened in the case where the object of processing not having the first film formed on the object of processing is at the second position.

### CROSS-REFERENCE TO RELATED APPLICATIONS

This application is based upon and claims the benefit of priority from the prior Japanese Patent Application No. 2010-53616, filed on Mar. 10, 2010; the entire contents of which are incorporated herein by reference.

### FIELD

Embodiments described herein relate generally to a method for manufacturing a device and a manufacturing apparatus.

### BACKGROUND

Films are formed using sputtering in the manufacturing of semiconductor devices. In such sputtering, accelerated charged particles (e.g., argon ions, etc.) impact a sputtering target; the impact energy sputters atoms of the sputtering target; and the atoms of the sputtering target adhere to an object of processing placed on a side opposing the sputtering target.

For example, ITO (Indium Tin Oxide) films used as electrodes and the like can be formed using sputtering.

For such sputtering, technology has been discussed in which an object of processing is placed on the front side of the sputtering target when forming the ITO film, and the ITO film is formed on the surface of the placed object of processing (for example, refer to JP-A 2005-181670 (Kokai)). Further, technology has been discussed in which the object of processing moves across the front side of the sputtering target when forming an ITO film on the surface of the object of processing (refer to JP-A 10-280127 (Kokai) (1998)).

However, as in the technology discussed in JP-A 2005-181670 (Kokai) and JP-A 10-280127 (Kokai) (1998), the formed ITO film may be damaged by the charged particles and sputtered particles having high kinetic energy when the object of processing is placed on the front side of the sputtering target or the object of processing simply moves across the front side of the sputtering target. Moreover, in the case where the ITO film is damaged, there is a risk that deterioration of the characteristics of the formed film such as an increase of the contact resistance may occur.

### BRIEF DESCRIPTION OF THE DRAWINGS

FIG. 1 is a schematic view illustrating main components of a semiconductor manufacturing apparatus according to an embodiment;

FIGS. 2A and 2B are schematic views illustrating main components of a semiconductor manufacturing apparatus according to a comparative example;

FIGS. 3A and 3B are schematic views illustrating a relationship between a placement position of an object of processing and an occurrence of damage;

FIGS. 4A and 4B are schematic views illustrating effects of a particle control unit;

FIGS. 5A to 5E are schematic views illustrating a first passage control unit and a second passage control unit; and

FIGS. 6A to 6C are schematic views illustrating main components of a semiconductor manufacturing apparatus according to one other embodiment.

### DETAILED DESCRIPTION

In one embodiment, a method is disclosed for manufacturing a device including forming a film on an object of processing using sputtering. The method can form a first film of a first sputtered particle on the object of processing at a first position. The first sputtered particle travels in a direction intersecting a major surface of a sputtering target. The object of processing and the sputtering target do not overlap as viewed in plan at the first position. In addition, the method can form a second film of a second sputtered particle on the first film at a second position. The second sputtered particle travels in a direction substantially orthogonal to the major surface of the sputtering target. The object of processing and the sputtering target at least partially overlap as viewed in plan at the second position. The second sputtered particle is screened in the case where the object of processing not having the first film formed on the object of processing is at the second position.

Exemplary embodiments of the invention will now be described with reference to the drawings. Similar components in the drawings are marked with like reference numerals, and a detailed description is omitted as appropriate.

First, a semiconductor manufacturing apparatus according to this embodiment will be described.

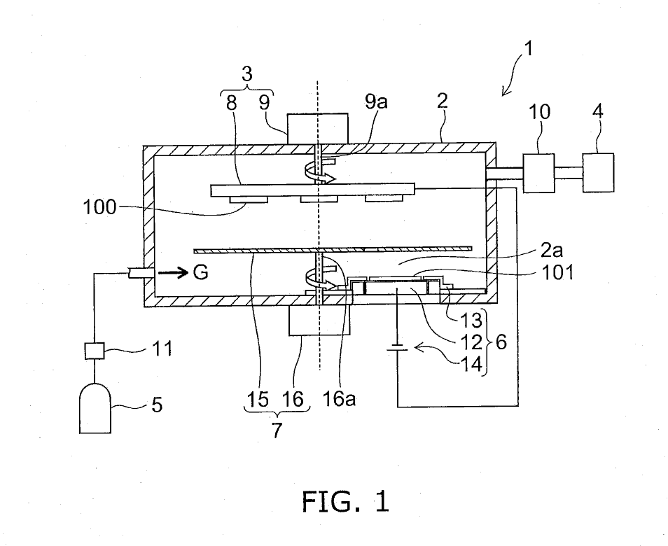

FIG. 1 is a schematic view illustrating main components of the semiconductor manufacturing apparatus according to this embodiment.

As illustrated in FIG. 1, a semiconductor manufacturing apparatus 1 includes a processing container 2 (chamber), a placement unit 3, a pressure reduction unit 4, a gas supply unit 5, a sputtering unit 6, and a particle control unit 7.

The processing container 2 has, for example, a substantially cylindrical configuration in which both ends are closed and has an airtight structure capable of maintaining an atmosphere having a pressure lower than atmospheric pressure.

The placement unit 3 has a holder 8 and a drive unit 9.

The holder 8 is provided in the interior of the processing container 2. A not-illustrated electrostatic chuck and the like are provided in the holder 8 and are capable of holding an object of processing (e.g., a wafer) 100 placed thereon. A not-illustrated mechanical chuck (e.g., that holds by dropping the object of processing into a recessed cavity, presses down the object of processing with a pin and the like, etc.) may be provided in the holder 8.

The drive unit 9 is provided outside the processing container 2. A drive axis 9a is provided in the drive unit 9. The drive axis 9a passes through a wall face of the processing container 2; and the holder 8 is mounted onto the end of the drive axis 9a. The drive unit 9 rotationally drives the holder 8 via the drive axis 9a. The drive unit 9 also may drive the holder 8 up and down to change the distance between the holder 8 and a sputtering target 101.

In other words, the placement unit 3 can place the object of processing, hold the object of processing, and change the relative position of the object of processing with respect to the sputtering target 101.

The pressure reduction unit 4 is connected to a side wall of the processing container 2 via a pressure control unit 10. The pressure reduction unit 4 may be connected via the pressure control unit 10 at a location other than the side wall of the processing container 2 (e.g., the bottom portion of the processing container 2, etc.). The pressure reduction unit 4 reduces the pressure of the interior of the processing container 2 to a prescribed pressure. The pressure control unit 10 controls the internal pressure of the processing container 2 to the prescribed pressure based on an output of a not-illustrated vacuum gauge and the like that detect the internal pressure of the processing container 2. The pressure reduction unit 4 may be, for example, a turbo molecular pump (TMP) and the like. The pressure control unit 10 may be, for example, an auto pressure controller (APC) and the like.

The gas supply unit 5 is connected to a side wall of the processing container 2 via a flow rate control unit 11. The gas supply unit 5 may be connected via the flow rate control unit 11 at a location other than the side wall of the processing container 2. For example, the gas supply unit 5 may be connected to the processing container 2 via the flow rate control unit 11 to supply a processing gas G uniformly from multiple locations around the sputtering target 101. The gas supply unit 5 supplies the processing gas G via the flow rate control unit 11 to a region 2a in the interior of the processing container 2 where plasma is produced. The flow rate control unit 11 controls the supply amount of the processing gas G. The gas supply unit 5 may be, for example, a pressure cylinder and the like that stores the pressurized processing gas G. The flow rate control unit 11 may be, for example, a mass flow controller (MFC).

The processing gas G may be, for example, a noble gas such as argon (Ar), krypton (Kr), and xenon (Xe). A noble gas with oxygen gas (O₂), etc., also may be used. For example, a noble gas (e.g., argon (Ar), etc.) and oxygen gas (O₂) may be used in the case where an ITO (Indium Tin Oxide) film is formed. In such a case, hydrogen gas (H₂) and/or water vapor (H₂O) also may be added.

An electrode unit 12, an anode ring 13, and a power source unit 14 are provided in the sputtering unit 6. The electrode unit 12 is provided to oppose the holder 8 and is capable of holding the sputtering target 101 provided in the interior of the processing container 2. For example, it is possible for the sputtering target 101 to be held using not-illustrated screws, holding members, etc.

The anode ring 13 is provided to enclose the periphery of the sputtering target 101. The anode ring 13 is provided to prevent ions of the processing gas G, etc., from impacting the electrode unit 12, etc.

The power source unit 14 applies a direct voltage to the electrode unit 12 and the holder 8. The power source unit 14 may be a direct-current power source. The electrode unit 12 may be a cathode; the holder 8 may be an anode; and it is possible to apply a bias therebetween. An RF power source (a high-frequency power source) also may be used as the power source unit 14.

Further, a magnet for controlling the intensity of the magnetic field occurring at the surface of the sputtering target 101, a cooling mechanism for cooling the sputtering target 101 via the electrode unit 12, etc., may be provided appropriately.

The sputtering target 101 may have, for example, a discal configuration and may be made of the same material as the film to be formed. For example, a sintered body including about 90 wt % of indium oxide (In₂O₃) and about 10 wt % of tin oxide (SnO₂) may be used in the case where an ITO (Indium Tin Oxide) film is formed.

Here, the formed film may be damaged by charged particles, sputtered particles having high kinetic energy, etc., in the case where the object of processing 100 is placed at a position (a second position, referred to as a front side of the sputtering target 101 hereinbelow) where the object of processing and the sputtering target 101 at least partially overlap as viewed in plan.

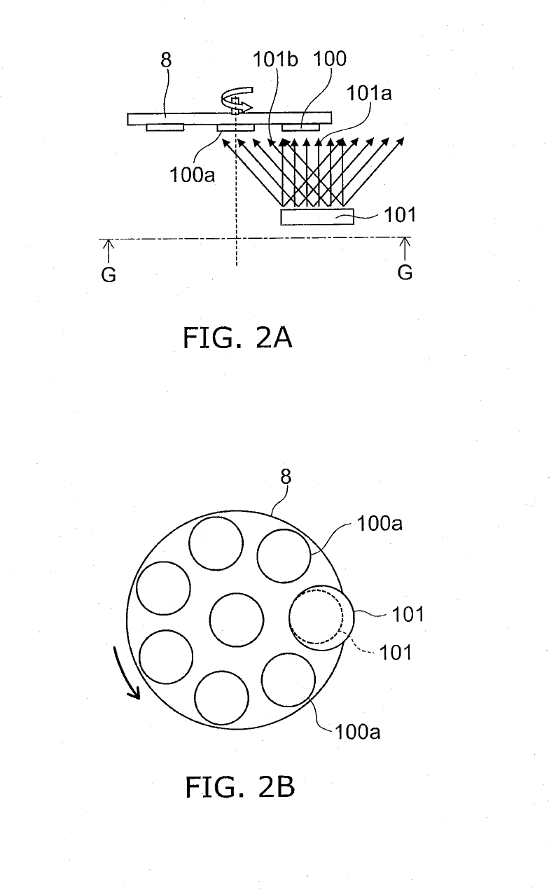

FIGS. 2A and 2B are schematic views illustrating main components of a semiconductor manufacturing apparatus according to a comparative example.

FIG. 2A is a schematic side view of the main components of the semiconductor manufacturing apparatus according to the comparative example. FIG. 2B is a view along arrows G-G of FIG. 2A.

As illustrated in FIG. 2A, sputtered particles 101a (second sputtered particles) are sputtered from the sputtering target 101 in a direction substantially orthogonal to the major surface of the sputtering target 101 and reach the surface of the object of processing 100 placed on the front side of the sputtering target 101 to form a film. On the other hand, sputtered particles 101b (first sputtered particles) are sputtered from the sputtering target 101 in a direction intersecting the major surface of the sputtering target 101 and reach the surface of an object of processing 100a placed at a position (a first position, e.g., a position adjacent to the object of processing 100 referred to as an adjacent position as appropriate hereinbelow) where the object of processing and the sputtering target 101 do not overlap as viewed in plan to form a film. In this case, sputtered particles 101a and sputtered particles 101b are substantially the same. However, first sputtered particle travelling in a direction and second sputtered particle travelling in a direction are different.

In such a case, the sputtered particles 101a have a high sputter amount and a high kinetic energy. Conversely, the sputtered particles 101b have a low sputter amount and a lower kinetic energy than the sputtered particles 101a. Therefore, the film formation rate increases for the object of processing placed on the front side of the sputtering target 101. However, the sputtered particles 101a have a high kinetic energy; and charged particles (e.g., argon ions, etc.) produced by plasma described below easily reach the object of processing placed on the front side of the sputtering target 101. Therefore, the film formed on the object of processing placed on the front side of the sputtering target 101 is damaged easily.

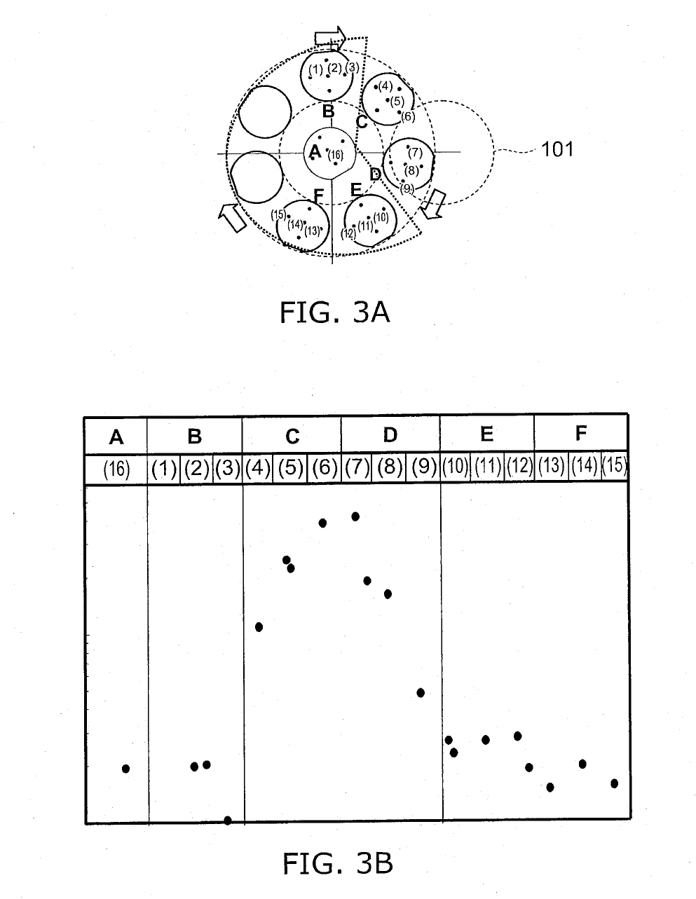

FIGS. 3A and 3B are schematic views illustrating the relationship between the placement position of the object of processing and the occurrence of damage. FIGS. 3A and 3B are schematic views illustrating the occurrence of damage (the increase of the contact resistance) in the case where an ITO film is formed on p-type GaN (gallium nitride) as one example.

FIG. 3A is a schematic view illustrating the positional relationship between the sputtering target 101 and objects of processing A to D and the measurement positions (1) to (16) of the contact resistance. FIG. 3B is a schematic view illustrating how the damage occurs, that is, the change of the contact resistance. The arrows in FIG. 3A indicate the movement direction of the object of processing (the rotation direction of the holder 8).

As illustrated in FIG. 3A and FIG. 3B, the contact resistance markedly increases for the objects of processing C and D placed on the front side of the sputtering target 101. Also, the increase of the contact resistance is high for the measurement positions proximal to the front side of the sputtering target 101; and the increase of the contact resistance is higher for the upstream side of the movement direction.

As a result of investigations of the inventors, knowledge was obtained that the increase of the contact resistance can be suppressed while increasing the film formation efficiency by first forming a film (the first film, referred to as a buffer layer hereinbelow) of the sputtered particles 101b having little damage and then forming a film (the second film) of the sputtered particles 101a by stacking onto the formed film (the buffer layer).

In other words, the knowledge was obtained that the increase of the contact resistance can be suppressed by forming the buffer layer of the sputtered particles 101b having little damage beforehand; and the film formation efficiency can be increased by rapidly forming the film of the sputtered particles 101a.

Therefore, in the semiconductor manufacturing apparatus 1, the particle control unit 7 is provided to control the sputtered particles.

As illustrated in FIG. 1, a control body 15 and a drive unit 16 are provided in the particle control unit 7.

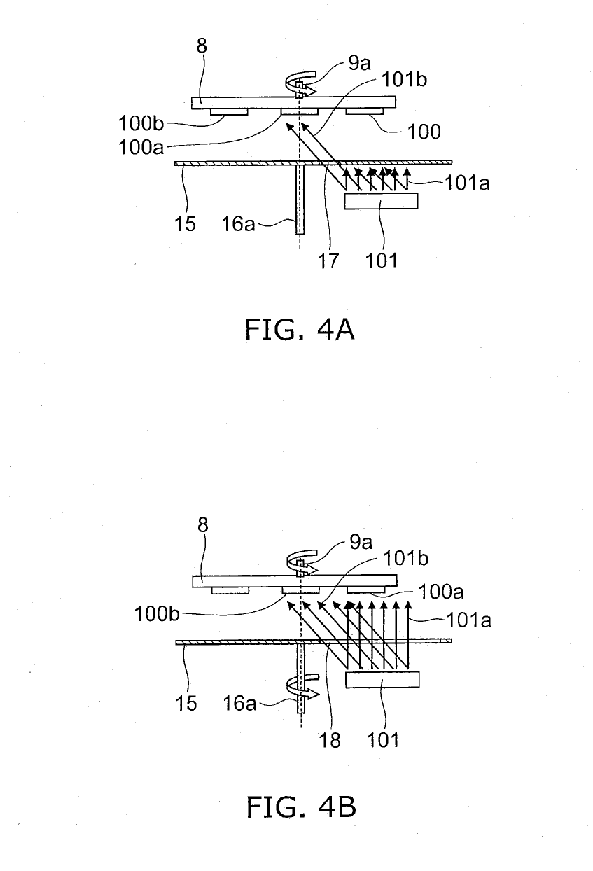

The control body 15 has a discal configuration and is provided between the holder 8 and the electrode unit 12. The space between the control body 15 and the electrode unit 12 is the region 2a where the plasma is produced. As described below, a first passage control unit 17 and a second passage control unit 18 are provided in the control body 15 (e.g., refer to FIGS. 4A and 4B). The first passage control unit 17 allows the sputtered particles 101b travelling in the direction intersecting the major surface of the sputtering target 101 to pass therethrough and screens the sputtered particles 101a travelling in the direction substantially orthogonal to the major surface of the sputtering target 101. The second passage control unit 18 allows at least the sputtered particles 101a to pass therethrough.

The drive unit 16 is provided outside the processing container 2. A drive axis 16a is provided in the drive unit 16. The drive axis 16a passes through the wall face of the processing container 2; and the control body 15 is mounted on the end of the drive axis 16a. The drive unit 16 rotationally drives or reciprocatively drives the control body 15 via the drive axis 16a. In other words, the drive unit 16 can change the relative positions of the first passage control unit 17 and the second passage control unit 18 with respect to the sputtering target 101.

FIGS. 4A and 4B are schematic views illustrating effects of the particle control unit.

FIG. 4A is the case where the film of the sputtered particles 101b are formed; and FIG. 4B is the case where the films of the sputtered particles 101a or the sputtered particles 101b are formed. To avoid complexity, the sputtered particles sputtered in the diametrically outward direction of the holder 8 are not illustrated. As illustrated in FIG. 4A, by positioning the first passage control unit 17 on the front side of the sputtering target 101, the sputtered particles 101a travelling toward the object of processing 100 positioned on the front side of the sputtering target 101 can be screened. On the other hand, the sputtered particles 101b travelling toward the object of processing 100a at the adjacent position can pass through the first passage control unit 17. Therefore, films of the sputtered particles 101b can be formed. In such a case, the passage amount of the sputtered particles 101b can be controlled by the first passage control unit 17. The charged particles (e.g., the argon ions, etc.) travelling toward the object of processing 100 also are screened; and the charged particles travelling toward the object of processing 100a also are suppressed. Therefore, the occurrence of damage of the object of processing 100 can be suppressed. Also, the buffer layer having little damage can be formed on the object of processing 100a.

In other words, when the drive unit 16 changes the position of the first passage control unit 17 to cause the sputtering target 101 and the first passage control unit 17 to overlap as viewed in plan and the first passage control unit 17 allows the sputtered particles 101b to pass therethrough, a film (the buffer layer) is formed on the object of processing 100a at the position (the adjacent position) where the object of processing and the sputtering target do not overlap as viewed in plan.

The first passage control unit 17 screens the sputtered particles 101a. Thereby, the first passage control unit 17 suppresses the sputtered particles 101a reaching the object of processing 100 at the position (the front side) where the object of processing and the sputtering target 101 at least partially overlap as viewed in plan.

Then, as illustrated in FIG. 4B, the holder 8 is rotated to position the object of processing 100a having the buffer layer formed thereon on the front side of the sputtering target 101. Also, the control body 15 is rotated or reciprocated to position the second passage control unit 18 on the front side of the sputtering target 101.

Thus, the sputtered particles 101a travelling toward the object of processing 100a positioned on the front side of the sputtering target 101 can pass through the second passage control unit 18. Therefore, the sputtered particles 101a can stack onto the buffer layer to form a film of the sputtered particles 101a. The film formation rate is high for the film formed of the sputtered particles 101a. Therefore, the film formation efficiency can be increased.

On the other hand, the sputtered particles 101b also can pass through the second passage control unit 18. Therefore, a buffer layer can be formed on an object of processing 100b at the adjacent position. Therefore, films having improved characteristics can be formed thereafter sequentially and continuously by rotating the holder 8.

In other words, when the drive unit 16 changes the position of the second passage control unit 18 to cause the sputtering target 101 and the second passage control unit 18 to overlap as viewed in plan, the second passage control unit 18 allows the sputtered particles 101a to pass therethrough and a film is formed on the film (on the buffer layer) of the object of processing 100a on the front side.

The second passage control unit 18 also allows the sputtered particles 101b to pass therethrough to form a film (a buffer layer) on the object of processing 100b at the adjacent position.

The object of processing having the buffer layer formed thereon at the adjacent position is moved to the front side by the placement unit 3.

Films also may be formed while appropriately switching between the first passage control unit 17 and the second passage control unit 18.

The first passage control unit 17 and the second passage control unit 18 will now be described further. To screen the sputtered particles 101a, it is sufficient for the first passage control unit to have a configuration capable of screening at least the portion where the sputtering target 101 and the track of the movement of the object of processing overlap as viewed in plan. The size of the first passage control unit may be determined appropriately by experiments, simulations, etc., considering the passage amount of the sputtered particles 101b toward the object of processing at the adjacent position. For example, the determination may be made appropriately by experiments, simulations, etc., considering the position, distance, angle, etc., of the object of processing at the adjacent position.

The second passage control unit 18 may be determined appropriately by experiments, simulations, etc., considering the passage amount of the sputtered particles 101a toward the object of processing positioned on the front side of the sputtering target 101 and the passage amount of the sputtered particles 101b toward the object of processing at the adjacent position. For example, the determination may be made appropriately by experiments, simulations, etc., considering the positions, distances, angles, etc., of the objects of processing.

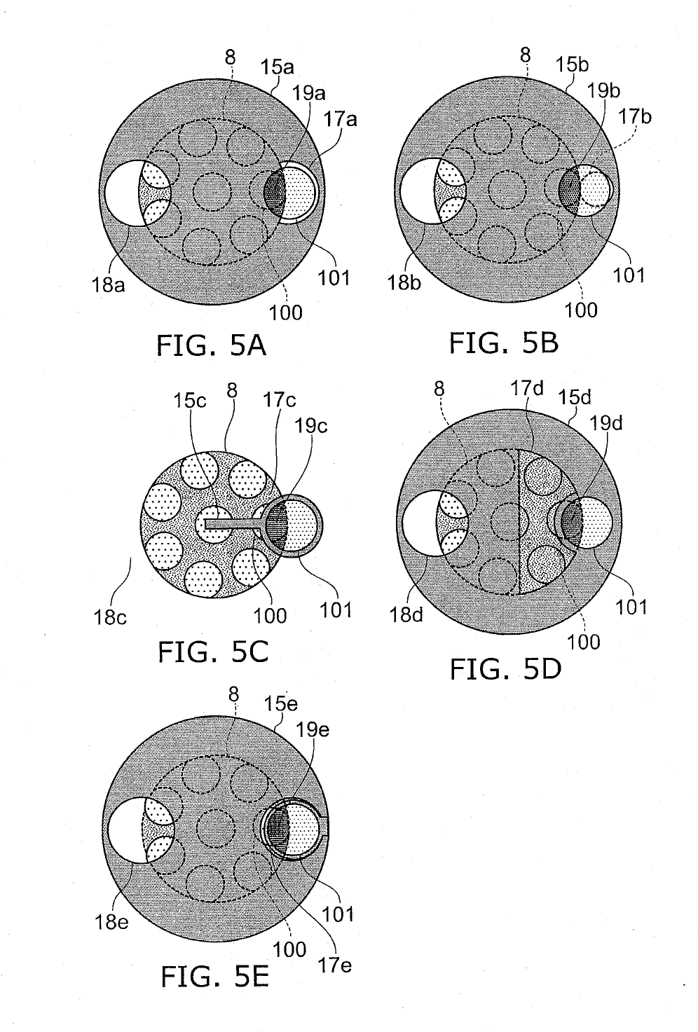

FIGS. 5A to 5E are schematic views illustrating the first passage control unit and the second passage control unit.

As illustrated in FIG. 5A, a control body 15a may include a first passage control unit 17a made of a substantially semicircular hole and a second passage control unit 18a made of a circular hole. The first passage control unit 17a is shifted in the diametrically outward direction of the holder 8 to screen a portion 19a where the sputtering target 101 and the track of the movement of the object of processing 100 overlap as viewed in plan. The diametrical dimension of the second passage control unit 18a may be greater than the diametrical dimension of the sputtering target 101.

As illustrated in FIG. 5B, a control body 15b may include a first passage control unit 17b made of a circular hole and a second passage control unit 18b made of a circular hole. The first passage control unit 17b is shifted in the diametrically outward direction of the holder 8 to screen a portion 19b where the sputtering target 101 and the track of the movement of the object of processing 100 overlap as viewed in plan. The diametrical dimension of the second passage control unit 18b may be greater than the diametrical dimension of the sputtering target 101.

As illustrated in FIG. 5C, a circular plate-like body (second circular plate-like body) may be provided on a control body 15c to screen a portion 19c where the sputtering target 101 and the track of the movement of the object of processing 100 overlap as viewed in plan; a first passage control unit 17c may be the circumferential edge proximity thereof; and a second passage control unit 18c may be the remaining space. In such a case, the sputtered particles 101b travel from the circumferential edge proximity of the plate-like body (the first passage control unit 17c) toward the object of processing at the adjacent position.

As illustrated in FIG. 5D, a control body 15d may include a first passage control unit 17d made of a substantially semicircular hole and a second passage control unit 18d made of a circular hole. The first passage control unit 17d is shifted in the diametrically inward direction of the holder 8 to screen the portion 19a where the sputtering target 101 and the track of the movement of the object of processing 100 overlap as viewed in plan. The diametrical dimension of the second passage control unit 18d may be greater than the diametrical dimension of the sputtering target 101.

As illustrated in FIG. 5E, a circular plate-like body (first circular plate-like body) may be provided on a control body 15e to screen a portion 19e where the sputtering target 101 and the track of the movement of the object of processing 100 overlap as viewed in plan; and a first passage control unit 17e made of a hole having a slit configuration may be provided at the circumferential edge of the circular plate-like body. A second passage control unit 18e made of a circular hole also may be provided. The diametrical dimension of the second passage control unit 18e may be greater than the diametrical dimension of the sputtering target 101.

Effects of the semiconductor manufacturing apparatus 1 according to this embodiment will now be described.

First, an object of processing (e.g., a wafer) is transferred into the processing container 2 by a not-illustrated transfer apparatus, placed on the holder 8, and held. At this time, the first passage control unit 17 is positioned on the front side of the sputtering target 101.

Then, the pressure in the processing container 2 is reduced to a prescribed pressure by the pressure reduction unit 4. At this time, the pressure in the processing container 2 is adjusted by the pressure control unit 10.

Then, the processing gas G is supplied from the gas supply unit 5 via the flow rate control unit 11 to the region 2a in the processing container 2 where the plasma is produced. At this time, the flow rate of the processing gas G supplied is controlled by the flow rate control unit 11. In the case where, for example, an ITO (Indium Tin Oxide) film is formed, a noble gas (e.g., argon (Ar), etc.) and oxygen gas (O₂) are supplied. Only a noble gas (e.g., argon (Ar), etc.) or a noble gas (e.g., argon (Ar), etc.) and hydrogen gas (H₂) may be supplied.

Then, the power source unit 14 applies a direct voltage to the electrode unit 12 (the sputtering target 101) and the holder 8. In such a case, the electrode unit 12 may be a cathode; the holder may be an anode; and it is possible to apply a bias therebetween.

Then, plasma is produced; the supplied processing gas G is excited and activated by the produced plasma; and charged particles (e.g., argon ions, etc.) are produced.

The produced argon ions (Ar⁺) are accelerated proximally to the sputtering target 101, i.e., the cathode side, and impact the sputtering target 101. The atoms of the sputtering target are sputtered as the sputtered particles 101a and 101b due to the impact energy. In such a case, the first passage control unit 17 screens the sputtered particles 101a travelling toward the object of processing positioned on the front side of the sputtering target 101. The charged particles travelling toward the object of processing positioned on the front side of the sputtering target 101 also are screened.

On the other hand, the sputtered particles 101b travelling toward the object of processing at the adjacent position can pass through the first passage control unit 17. Therefore, a film of the sputtered particles 101b is formed on the object of processing at the adjacent position. At this time, the charged particles travelling toward the object of processing at the adjacent position also are suppressed.

Therefore, the occurrence of damage of the object of processing positioned on the front side of the sputtering target 101 can be suppressed. Further, a buffer layer having little damage can be formed on the object of processing at the adjacent position.

Then, the object of processing having the buffer layer formed thereon is positioned on the front side of the sputtering target 101 by rotating the holder 8. The control body 15 is rotated or reciprocated to position the second passage control unit 18 on the front side of the sputtering target 101.

The sputtered particles 101a travelling toward the object of processing positioned on the front side of the sputtering target 101 can pass through the second passage control unit 18. Therefore, the sputtered particles 101a are stacked onto the buffer layer to form a film of the sputtered particles 101a. On the other hand, the sputtered particles 101b also can pass through the second passage control unit 18. Therefore, a buffer layer is formed on the object of processing at the adjacent position.

Therefore, the film formation efficiency can be increased for the object of processing positioned on the front side of the sputtering target 101. Simultaneously, the buffer layer can be formed beforehand on the next object of processing to be moved to the front side of the sputtering target 101.

Thereafter, the films are formed sequentially and continuously on the objects of processing by rotating the holder 8.

The films can be formed also by appropriately switching between the first passage control unit 17 and the second passage control unit 18.

For example, the films may be formed by timing the switching between the first passage control unit 17 and the second passage control unit 18 as recited below.

First, the first passage control unit 17 is positioned on the front side of the sputtering target 101; the holder 8 is rotated an amount in this state; and a buffer layer of the sputtered particles 101b is formed uniformly on all of the placed objects of processing. Then, the control body 15 is rotated or reciprocated to position the second passage control unit 18 on the front side of the sputtering target 101. Then, a film of the sputtered particles 101a is formed by stacking on the buffer layer.

The rotation operation of the holder 8 may be performed continuously at a prescribed speed or may be performed intermittently.

The objects of processing for which the processing is complete are transferred out of the processing container 2 by the not-illustrated transfer apparatus. Thereafter, the formation of the films described above is repeated as necessary.

According to this embodiment, the first passage control unit 17 can screen the sputtered particles 101a travelling toward the object of processing positioned on the front side of the sputtering target 101. On the other hand, the sputtered particles 101b travelling toward the object of processing at the adjacent position are allowed to pass through. Therefore, the buffer layer can be formed beforehand on the next object of processing to be moved to the front side of the sputtering target 101. In such a case, the passage amount of the sputtered particles 101b can be controlled by appropriately setting the disposition, size, etc., of the first passage control unit 17. The charged particles travelling toward the object of processing positioned on the front side of the sputtering target 101 also can be screened; and the charged particles travelling toward the object of processing at the adjacent position also can be suppressed.

Therefore, the occurrence of damage of the object of processing positioned on the front side of the sputtering target 101 can be suppressed. Further, the buffer layer having little damage can be formed beforehand on the object of processing at the adjacent position.

Also, the second passage control unit 18 allows the sputtered particles 101a to pass therethrough to increase the film formation efficiency of the object of processing positioned on the front side of the sputtering target 101. Simultaneously, the buffer layer can be formed beforehand on the next object of processing to be moved to the front side of the sputtering target 101.

A semiconductor manufacturing apparatus according to one other embodiment will now be described.

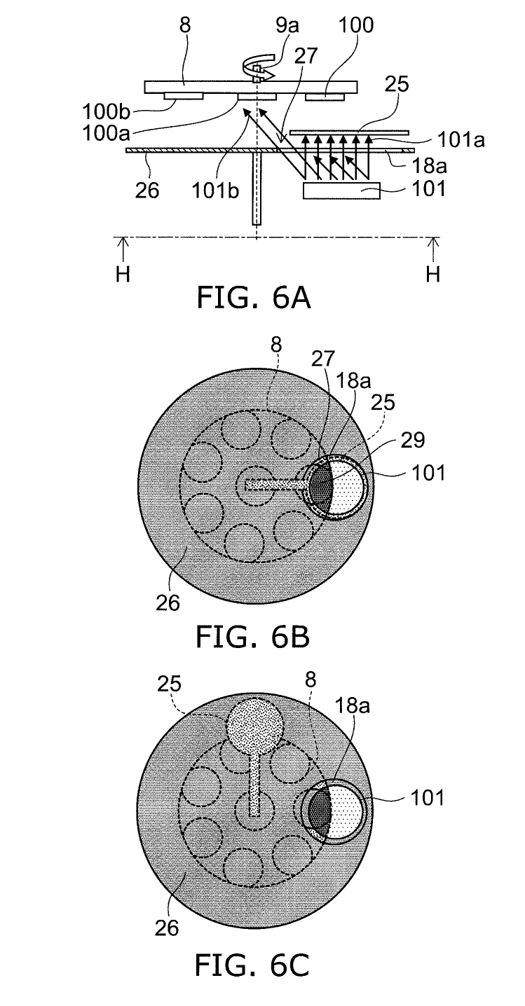

FIGS. 6A to 6C are schematic views illustrating main components of the semiconductor manufacturing apparatus according to the one other embodiment.

FIG. 6A is a schematic side view of the main components of the semiconductor manufacturing apparatus according to the one other embodiment. FIG. 6B is a view along arrows H-H of FIG. 6A. FIG. 6B is the case where a first passage control unit 27 is formed. FIG. 6C is the case where the second passage control unit 18a is opened. To avoid complexity, the sputtered particles sputtered toward the diametrically outward direction of the holder 8 are not illustrated.

As illustrated in FIGS. 6A to 6C, a first particle control unit 25 and a second particle control unit 26 are provided in this embodiment. The first particle control unit 25 includes a circular plate-like body that screens a portion 29 where the sputtering target 101 and the track of the movement of the object of processing 100 overlap as viewed in plan.

The second particle control unit 26 includes the second passage control unit 18a made of a circular hole. The diametrical dimension of the second passage control unit 18a is greater than the diametrical dimension of the sputtering target 101; and the second passage control unit 18a is positioned on the front side of the sputtering target 101.

As illustrated in FIG. 6B, the first particle control unit 25 and the second particle control unit 26 cooperate to form the first passage control unit 27. In other words, the first passage control unit 27 made of a hole having a slit configuration is formed at the circumferential edge of the circular plate-like body provided in the first particle control unit 25 by the second passage control unit 18a made of the circular hole overlapping the circular plate-like body.

As illustrated in FIG. 6C, the second passage control unit 18a made of the circular hole can be opened by shifting the positions of the second passage control unit 18a and the circular plate-like body provided in the first particle control unit 25.

Therefore, by using the state illustrated in FIGS. 6A and 6B, the first passage control unit 27 can be formed to screen the sputtered particles 101a travelling toward the object of processing 100 positioned on the front side of the sputtering target 101. On the other hand, the sputtered particles 101b travelling toward the object of processing at the adjacent position can be passed therethrough. Therefore, a buffer layer can be formed on the next the object of processing 100a to be moved to the front side of the sputtering target 101. In such a case, the disposition, size, etc., of the first passage control unit 27 can be appropriately set to control the passage amount of the sputtered particles 101b. The charged particles travelling toward the object of processing 100 positioned on the front side of the sputtering target 101 also can be screened; and the charged particles travelling toward the object of processing 100a at the adjacent position also can be suppressed.

Therefore, the occurrence of the damage of the object of processing 100 positioned on the front side of the sputtering target 101 can be suppressed. Further, the buffer layer having little damage can be formed beforehand on the object of processing 100a at the adjacent position.

By using the state illustrated in FIG. 6C, the film formation efficiency of the object of processing positioned on the front side of the sputtering target 101 can be increased by opening the second passage control unit 18a to allow the sputtered particles 101a to pass therethrough. Simultaneously, the buffer layer can be formed beforehand on the next object of processing to be moved to the front side of the sputtering target 101.

In this embodiment as well, operations and effects similar to those of the semiconductor manufacturing apparatus 1 described above can be obtained. In this case, the first particle control unit 25, which is the moving portion, is small. Therefore, the drive system and the control system can be simplified.

A method for manufacturing a semiconductor device according to this embodiment will now be described.

Herein, the manufacturing processes of the semiconductor device generally include the so-called front-end processes such as the processes that form a circuit pattern on a surface of a base member (e.g., a wafer) by film formation, resist coating, exposing, developing, etching, resist removal, etc., the inspection processes, cleaning processes, heat treatment processes, impurity introduction processes, diffusion processes, planarizing processes, etc. The so-called back-end processes include the assembly processes of dicing, mounting, bonding, encapsulation, etc., the functional and reliability inspection processes, etc.

In the method for manufacturing the semiconductor device according to this embodiment, a film can be formed by the following procedure for a process forming a film (a film formation process) on an object of processing using sputtering. The film formation also may be performed using the semiconductor manufacturing apparatuses described above. Other than the film formation process, conventional technology can be applied, and a description thereof is therefore omitted.

Herein, the case is illustrated where an ITO film is formed on a layer made of p-type GaN (gallium nitride), i.e., a p-type semiconductor layer, as one example.

In the case where the ITO film is formed on p-type GaN (gallium nitride) using sputtering, a sintered body including about 90 wt % of indium oxide (In₂O₃) and about 10 wt % of tin oxide (SnO₂) may be used as the sputtering target. The processing gas G may include argon (Ar) and oxygen with, for example, a flow rate of argon (Ar) of about 30 sccm, a flow rate of oxygen of about 0.5 sccm, and a gas pressure of about 0.67 Pa. The pressure of the processing environment may be about 1×10⁻⁵ Pa. The DC electro-discharge power may be about 100 W.

First, a first ITO film of the sputtered particles 101b travelling in a direction intersecting the major surface of the sputtering target 101 is formed as a buffer layer on the p-type GaN (the gallium nitride).

In such a case, the thickness of the first ITO film as the buffer layer may be, for example, about 1 nm (nanometer).

For example, the first ITO film may be formed as the buffer layer on the object of processing placed adjacent to the object of processing positioned on the front side of the sputtering target 101 by allowing the sputtered particles 101b travelling toward the object of processing at the adjacent position to pass through while screening the sputtered particles 101a travelling in the direction substantially orthogonal to the major surface of the sputtering target 101.

In other words, the first ITO film (the buffer layer) of the sputtered particles 101b travelling in the direction intersecting the major surface of the sputtering target 101 is formed on the object of processing at the position (the adjacent position) where the object of processing and the sputtering target 101 do not overlap as viewed in plan.

The sputtered particles 101a are screened in the case where the object of processing not having the first ITO film (the buffer layer) formed thereon is at the position (the front side) where the object of processing and the sputtering target 101 at least partially overlap as viewed in plan.

Then, a second ITO film of the sputtered particles 101a travelling in the direction substantially orthogonal to the major surface of the sputtering target 101 is formed on the first ITO film with the desired thickness.

For example, the second ITO film is formed by moving the object of processing having the first ITO film (the buffer layer) formed thereon to be positioned on the front side of the sputtering target 101 and stacking the second ITO film of the sputtered particles 101a with the desired thickness on the first ITO film (the buffer layer).

At this time, in the case where the next object of processing to have the ITO film formed thereon is placed in the position toward which the sputtered particles 101b travel, the first ITO film (the buffer layer) can be formed at such a position while forming the second ITO film on the front side of the sputtering target 101. Thus, the formation of the first ITO film (the buffer layer) and the formation of the second ITO film can be performed sequentially and continuously.

In other words, the second ITO film of the sputtered particles 101a travelling in the direction substantially orthogonal to the major surface of the sputtering target 101 is formed on the first ITO film (the buffer layer) at the position (the front side) where the object of processing and the sputtering target 101 at least partially overlap as viewed in plan.

According to this embodiment, a film (the buffer layer) of the sputtered particles 101b having lower kinetic energy is formed beforehand with little damage; and a film of the sputtered particles 101a can be formed by stacking on the formed film (the buffer layer). Therefore, the increase of the contact resistance can be suppressed; and the film formation efficiency can be increased.

Although the case is illustrated as one example where an ITO film is formed on a p-type semiconductor layer, the invention is not limited thereto. Applications are possible also in the case where the ITO film is formed on a layer formed from other materials. For example, applications are possible in the case where the ITO film is formed on a layer made of n-type GaN (gallium nitride) which is an n-type semiconductor layer.

This embodiment is described hereinabove. However, the invention is not limited to such descriptions.

Design modifications made appropriately by one skilled in the art in regard to the embodiments described above also are included in the scope of the invention to the extent that features of the invention are included.

For example, the configurations, dimensions, material qualities, numbers, dispositions, etc., of the components included in the semiconductor manufacturing apparatus 1 are not limited to the examples herein and may be modified appropriately.

Further, additions, omissions, or condition modifications of processes made appropriately by one skilled in the art in regard to the embodiments described above are included in the scope of the invention to the extent that features of the invention are included.

Furthermore, the components included in the embodiments described above may be combined within the extent of feasibility; and such combinations also are included in the scope of the invention to the extent that features of the invention are included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A method for manufacturing a device including forming a film on an object of processing using sputtering, the method comprising:
forming a first film of a first sputtered particle on the object of processing at a first position, the first sputtered particle travelling in a direction intersecting a major surface of a sputtering target, the object of processing and the sputtering target not overlapping as viewed in plan at the first position; and
forming a second film of a second sputtered particle on the first film at a second position, the second sputtered particle travelling in a direction substantially orthogonal to the major surface of the sputtering target, the object of processing and the sputtering target at least partially overlapping as viewed in plan at the second position,
the second sputtered particle being screened in the case where the object of processing not having the first film formed on the object of processing is at the second position.

2. The method according to claim 1, wherein in the case where the object of processing having the first film formed on the object of processing is at the second position:
the second film of the second sputtered particle is formed on the first film at the second position; and
the first film of the first sputtered particle is formed on the object of processing at the first position.

3. The method according to claim 1, wherein the forming of the second film on the first film includes forming the second film of the second sputtered particle with higher film formation rate than the first sputtered particle.

4. A manufacturing apparatus, comprising:
a processing container;
a pressure reduction unit reducing a pressure of an interior of the processing container to a prescribed pressure;
an electrode unit capable of holding a sputtering target provided in the interior of the processing container;
a power source unit applying a voltage to the electrode unit;
a gas supply unit supplying a processing gas to the interior of the processing container;
a placement unit placing the object of processing and changing a relative position of the object of processing with respect to the sputtering target;
a first passage control unit allowing a first sputtered particle travelling in a direction intersecting a major surface of the sputtering target to pass through the first passage control unit while screening a second sputtered particle travelling in a direction substantially orthogonal to the major surface of the sputtering target;
a second passage control unit allowing at least the second sputtered particle to pass through the second passage control unit; and
a drive unit changing a relative position of the first passage control unit with respect to the sputtering target and a relative position of the second passage control unit with respect to the sputtering target.

5. The apparatus according to claim 4, wherein the first passage control unit and the second passage control unit are provided in a control body, the control body is provided in the processing container and between the placement unit and the electrode unit.

6. The apparatus according to claim 5, wherein the first passage control unit and the second passage control unit are opening in the control body.

7. The apparatus according to claim 6, wherein the first passage control unit made of a substantially semicircular hole, the first passage control unit is shifted in the diametrically outward direction of the control body to screen a portion where the sputtering target and the track of the movement of the object of processing overlap as viewed in plan,
Wherein the second passage control unit made of a circular hole, a diametrical dimension of the second passage control unit is greater than a diametrical dimension of the sputtering target.

8. The apparatus according to claim 6, wherein the first passage control unit made of the circular hole, the first passage control unit is shifted in the diametrically outward direction of the control body to screen the portion,
Wherein the second passage control unit made of the circular hole, the diametrical dimension of the second passage control unit is greater than the diametrical dimension of the sputtering target.

9. The apparatus according to claim 6, wherein the first passage control unit made of a substantially semicircular hole, the first passage control unit is shifted in the diametrically inward direction of the control body to screen the portion,
Wherein the second passage control unit made of the circular hole, the diametrical dimension of the second passage control unit is greater than the diametrical dimension of the sputtering target.

10. The apparatus according to claim 6, a first circular plate-like body is provided on the control body to screen the portion, the first passage control unit having a slit configuration is provided at the circumferential edge of the first circular plate-like body,
Wherein the second passage control unit made of the circular hole, the diametrical dimension of the second passage control unit is greater than the diametrical dimension of the sputtering target.

11. The apparatus according to claim 5, a second circular plate-like body is provided with the control body to screen the portion, the first passage control unit is the circumferential edge proximity of the second circular plate-like body,
Wherein the second passage control unit is a remaining space around the second circular plate-like body and the control body.

12. The apparatus according to claim 4, wherein
the drive unit changes a position of the first passage control unit to cause the sputtering target and the first passage control unit to overlap as viewed in plan, and
the first passage control unit forms a first film on the object of processing at a first position by allowing the first sputtered particle to pass through the first passage control unit, the object of processing and the sputtering target overlapping as viewed in plan at the first position.

13. The apparatus according to claim 5, wherein the first passage control unit suppresses the second sputtered particle reaching the object of processing at a second position by screening the second sputtered particle, the object of processing and the sputtering target at least partially overlapping as viewed in plan at the second position.

14. The apparatus according to claim 4, wherein
the drive unit changes a position of the second passage control unit to cause the sputtering target and the second passage control unit to overlap as viewed in plan, and
the second passage control unit forms a second film on a first film of the object of processing at the second position by allowing the second sputtered particle to pass through the second passage control unit.

15. The apparatus according to claim 7, wherein the second passage control unit forms the first film on the object of processing at the first position by also allowing the first sputtered particle to pass through the second passage control unit.

16. The apparatus according to claim 4, wherein the first passage control unit screens a portion where a track of a change of a position of the object of processing overlaps the sputtering target as viewed in plan.

17. The apparatus according to claim 4, wherein a diametrical dimension of the second passage control unit is greater than a diametrical dimension of the sputtering target.

18. The apparatus according to claim 4, wherein the drive unit changes a position of the first passage control unit to cause the sputtering target and the first passage control unit to overlap as viewed in plan in the case where the object of processing not having a first film formed on the object of processing is at the second position.

19. The apparatus according to claim 4, wherein the drive unit changes a position of the second passage control unit to cause the sputtering target and the second passage control unit to overlap as viewed in plan in the case where the object of processing having a first film formed on the object of processing is at the second position.

20. The apparatus according to claim 4, wherein an object of processing having a first film formed on the object of processing at the first position is moved by the placement unit to the second position.
